(19) United States
(12) Patent Application Publication
(10) Pub. No.: US 2013/0328450 A1
(43) Pub. Date: Dec. 12, 2013

(54) PIEZOELECTRIC VIBRATING PIECE AND PIEZOELECTRIC DEVICE

(71) Applicant: NIHON DEMPA KOGYO CO., LTD., Tokyo (JP)

(72) Inventors: TAKEHIRO TAKAHASHI, SAITAMA (JP); SHUICHI MIZUSAWA, SAITAMA (JP)

(21) Appl. No.: 13/906,349

(22) Filed: May 31, 2013

(30) Foreign Application Priority Data
Jun. 12, 2012 (JP) 2012-132641

(51) Int. Cl. H01L 41/053; H01L 41/047

(52) U.S. Cl. CPC H01L 41/053; H01L 41/0475
USPC 310/348

(57) ABSTRACT

A piezoelectric vibrating piece includes a rectangular vibrator, a framing portion, and a connecting portion. The rectangular vibrator is configured to vibrate at a predetermined vibration frequency and includes excitation electrodes on both principal surfaces. The framing portion surrounds a peripheral area of the vibrator and includes a first framing body and a second framing body. The first framing body extends in a long side direction. The second framing body extends in a short side direction. The connecting portion connects the vibrator and the framing portion. The first framing body includes a depressed portion or an extruding part on one principal surface that extends in a long side direction. The piezoelectric vibrating piece further includes an extraction electrode extending from the excitation electrode via the connecting portion. The extraction electrode extends from one end to another end of the one principal surface of the first framing body.

### CROSS REFERENCE TO RELATED APPLICATIONS

This application claims the priority benefit of Japan application serial no. 2012-132641, filed on Jun. 12, 2012. The entirety of the above-mentioned patent application is hereby incorporated by reference herein and made a part of this specification.

### TECHNICAL FIELD

This disclosure relates to a piezoelectric vibrating piece where a framing portion is formed and a piezoelectric device.

### DESCRIPTION OF THE RELATED ART

A piezoelectric vibrating piece that includes a vibrator vibrating at a predetermined vibration frequency, a framing portion surrounding the vibrator, and a connecting portion connecting the vibrator and the framing portion is known. In this piezoelectric vibrating piece, a base plate and a lid plate are bonded on one principal surface and the other principal surface of the framing portion via a bonding material, respectively, to form a piezoelectric device. A pair of excitation electrodes is formed on both principal surfaces of the vibrator of the piezoelectric vibrating piece. Extraction electrodes are extracted from each excitation electrode to the framing portion. In the piezoelectric vibrating piece, increasing an electrical resistance of this extraction electrode increases the crystal impedance (CI), which is a problem. Accordingly, it is preferred that the extraction electrode be formed with a small electrical resistance due to an increased extraction electrode area or similar reason. For example, Japanese Unexamined Patent Application Publication No. 2006-311015 (hereinafter referred to as Patent Literature 1) discloses a piezoelectric vibrating piece where an area of the extraction electrode extracted to a stepped part between a vibrator and a peripheral portion formed at a peripheral area of the vibrator is formed large.

However, in Patent Literature 1, only a short and partial part of the entire path of the extraction electrode is formed large. A reduction in an electrical resistance of the entire extraction electrode is not described.

A need thus exists for a piezoelectric vibrating piece and a piezoelectric device which are not susceptible to the drawback mentioned above.

### SUMMARY

A piezoelectric vibrating piece according to a first aspect includes a vibrator, a framing portion, and a connecting portion. The vibrator has a rectangular shape and vibrates at a predetermined vibration frequency. The vibrator includes excitation electrodes on both principal surfaces. The framing portion surrounds a peripheral area of the vibrator. The framing portion includes a first framing body and a second framing body. The first framing body extends in a long side direction. The second framing body extends in a short side direction. The connecting portion connects the vibrator and the framing portion. The first framing body includes a depressed portion or an extruding part on one principal surface. The depressed portion or the extruding part extends in a long side direction. The piezoelectric vibrating piece further includes an extraction electrode extending from the excitation electrode via the connecting portion. The extraction electrode extends from one end to another end of the one principal surface of the first framing body. The first framing body includes the depressed portion or the extruding part.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is an exploded perspective view of a piezoelectric device 100;

FIG. 2 is a cross-sectional view taken along the line A-A of FIG. 1;

FIG. 3(a) is a plan view of a piezoelectric vibrating piece 130;

FIG. 3(b) is a plan view of the piezoelectric vibrating piece 130 where the surface at the −Y′-axis side of the piezoelectric vibrating piece 130 is transparently viewed from the +Y′-axis side;

FIG. 4(a) is a perspective view of the piezoelectric vibrating piece 130 on the surface at the −Y′-axis side;

FIG. 4(b) is a cross-sectional view taken along the line B-B of FIG. 1;

FIG. 5(a) is a plan view of a piezoelectric vibrating piece 230 on a surface at the −Y′-axis side viewed from the +Y′-axis side;

FIG. 5(b) is a perspective view of the piezoelectric vibrating piece 230 on a surface at the −Y′-axis side;

FIG. 6(a) is a plan view of a piezoelectric vibrating piece 330 on a surface at the −Y′-axis side transparently viewed from the +Y′-axis side;

FIG. 6(b) is a cross-sectional view of a piezoelectric device 300;

FIG. 7(a) is a plan view of a piezoelectric vibrating piece 430;

FIG. 7(b) is a cross-sectional view taken along the line D-D of FIG. 7(a);

FIG. 7(c) is a cross-sectional view taken along the line E-E of FIG. 7(a);

FIG. 8(a) is a perspective view of a piezoelectric vibrating piece 630 on a surface at the −Y′-axis side;

FIG. 8(b) is a cross-sectional view of a piezoelectric device 600;

FIG. 8(c) is a cross-sectional view of the piezoelectric device 600;

FIG. 9(a) is a plan view of a piezoelectric vibrating piece 730 at the +Y′-axis side;

FIG. 9(b) is a plan view of the piezoelectric vibrating piece 730 on the surface at the −Y′-axis side viewed from the +Y′-axis side;

FIG. 10(a) is a perspective view of the piezoelectric vibrating piece 730;

FIG. 10(b) is a cross-sectional view of a piezoelectric device 700;

FIG. 11(a) is a plan view of a piezoelectric vibrating piece 830 on the surface at the +Y′-axis side;

FIG. 11(b) is a plan view of the piezoelectric vibrating piece 830 on a surface at the −Y′-axis side;

FIG. 12(a) is a plan view of a piezoelectric vibrating piece 930 on a surface at the +Y′-axis side;

FIG. 12(b) is a plan view of the piezoelectric vibrating piece 930 on a surface at the −Y′-axis side;

FIG. 13(a) is a plan view of a piezoelectric vibrating piece 1030; and

FIG. 13(b) is a cross-sectional view of a piezoelectric device 1000.

### DETAILED DESCRIPTION

The preferred embodiments of this disclosure will be described with reference to the attached drawings. It will be understood that the scope of the disclosure is not limited to the described embodiments, unless otherwise stated.

### Constitution of a Piezoelectric Device 100 According to a First Embodiment

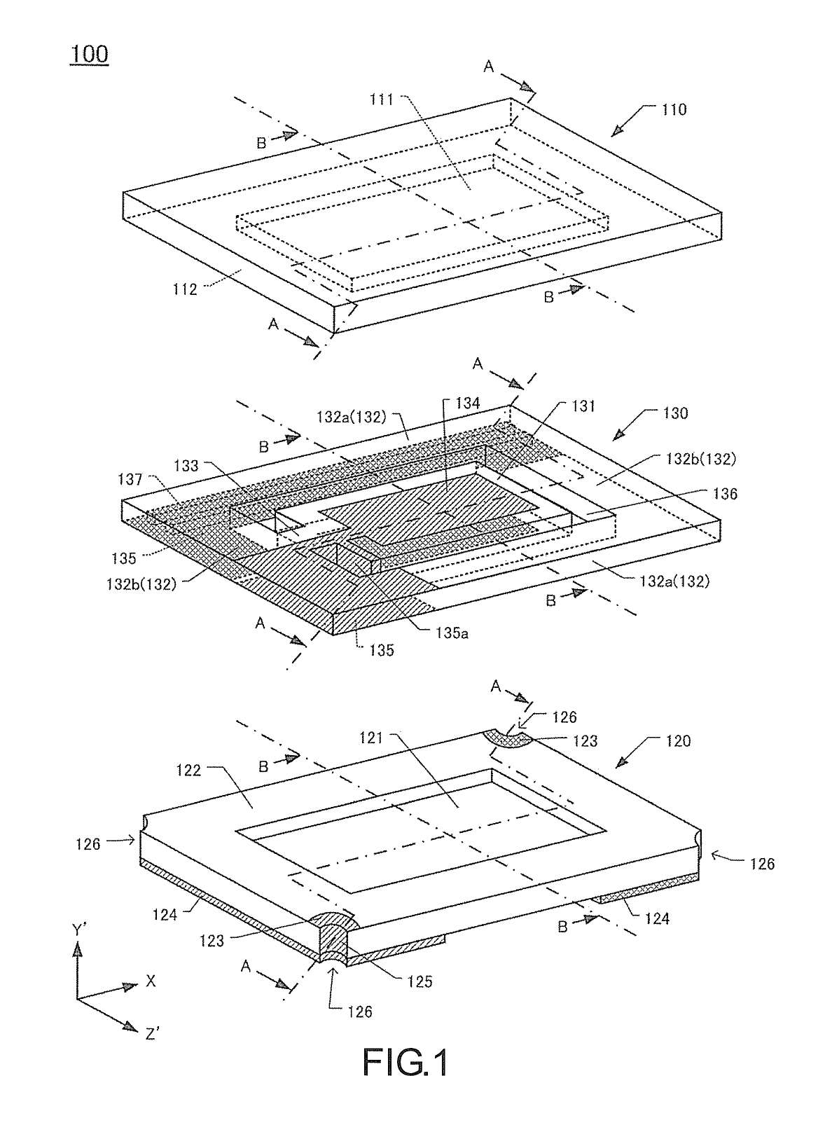

FIG. 1 is an exploded perspective view of the piezoelectric device 100. The piezoelectric device 100 includes a lid plate 110, a base plate 120, and a piezoelectric vibrating piece 130. An AT-cut quartz-crystal vibrating piece, for example, is employed for the piezoelectric vibrating piece 130. The AT-cut quartz-crystal vibrating piece has a principal surface (in the Y-Z plane) that is tilted by 35°15′ about the Y-axis of crystallographic axes (XYZ) in the direction from the Z-axis to the Y-axis around the X-axis. In the following description, the new axes tilted with reference to the axis directions of the AT-cut quartz-crystal vibrating piece are denoted as the Y′-axis and the Z′-axis. This disclosure defines the long side direction of the piezoelectric device 100 as the X-axis direction, the height direction of the piezoelectric device 100 as the Y′-axis direction, and the direction perpendicular to the X and Y′-axis directions as the Z′-axis direction.

The piezoelectric vibrating piece 130 includes a vibrator 131, a framing portion 132, and one connecting portions 133. The vibrator 131 vibrates at a predetermined vibration frequency and has a rectangular shape. The framing portion 132 surrounds the vibrator 131. The connecting portion 133 connects the vibrator 131 and the framing portion 132. The framing portion 132 includes a pair of first framing bodies 132a and a pair of second framing bodies 132b. The pair of first framing bodies 132a are disposed at the +Z′-axis side and the −Z′-axis side of the vibrator 131 and extend in the X-axis direction, which is the long side direction. The pair of second framing bodies 132b are disposed at the +X-axis side and the −X-axis side of the vibrator 131 and extend in the Z′-axis direction, which is the short side direction). The connecting portion 133 connects the center of the side at the −X-axis side of the vibrator 131 and the center at the −X-axis side of the second framing body 132b. In a region other than the connecting portion 133 between the vibrator 131 and the framing portion 132, a through groove 136 that passes through the piezoelectric vibrating piece 130 in the Y′-axis direction is formed. Excitation electrodes 134 are formed on surfaces at the +Y′-axis side and at the −Y′-axis side of the vibrator 131. An extraction electrode 135 is extracted from each excitation electrode 134 to the framing portion 132 through the connecting portion 133. Additionally, a depressed portion 137 is formed at the first framing body 132a at the −Z′-axis side on the surface at the −Y′-axis side. The depressed portion 137 is depressed at the +Y′-axis side.

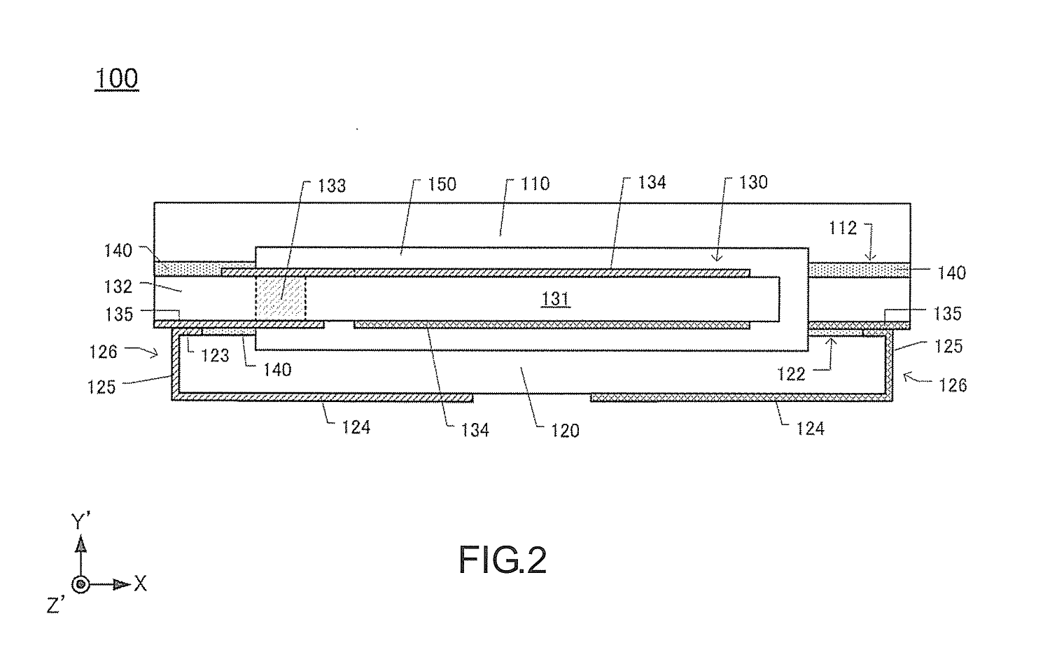

The base plate 120 includes a depressed portion 121, a bonding surface 122, and connecting electrodes 123 on the surface at the +Y′-axis side. The depressed portion 121 is depressed at −Y′-axis side. The bonding surface 122 surrounds the depressed portion 121. The connecting electrodes 123 are disposed at corners at the +X-axis side and the −Z′-axis side and at the −X-axis side and the +Z′-axis side of the bonding surface 122. The bonding surface 122 is to be bonded to the framing portion 132 on the surface at the −Y′-axis side of the piezoelectric vibrating piece 130 via a bonding material 140 (see FIG. 2). Additionally, a pair of mounting terminals 124 is formed on the surface at the −Y′-axis side of the base plate 120. Furthermore, castellations 126 are formed at four corners of side surfaces of the base plate 120. Castellation electrodes 125 are formed on side surfaces at the +X-axis side and the −Z′-axis side and at the −X-axis side and the +Z′-axis side of the castellation 126. The castellation electrode 125 electrically connects the connecting electrode 123 and the mounting terminal 124. The connecting electrode 123 formed on the corner at the −X-axis side and at the +Z′-axis side electrically connects to the extraction electrode 135 formed on the corner at the −X-axis side and the +Z′-axis side on the surface at the −Y-axis side of the piezoelectric vibrating piece 130. The connecting electrode 123 formed on the corner at the +X-axis side and at the −Z′-axis side electrically connects to the extraction electrode 135 formed on the corner at the +X-axis side and the −Z′-axis side on the surface at the −Y-axis side of piezoelectric vibrating piece 130.

The lid plate 110 includes a depressed portion 111 and a bonding surface 112 on the surface at the −Y′-axis side. The bonding surface 112 surrounds the depressed portion 111. The bonding surface 112 is to be bonded on the surface at the +Y′-axis side of the framing portion 132 of the piezoelectric vibrating piece 130 via the bonding material 140 (see FIG. 2).

FIG. 2 is a cross-sectional view taken along the line A-A of FIG. 1. The piezoelectric device 100 includes the lid plate 110 at the +Y′-axis side and the base plate 120 at the −Y′-axis side of the piezoelectric vibrating piece 130. Additionally, the piezoelectric device 100 includes a cavity 150 formed by the depressed portion 111 of the lid plate 110 and the depressed portion 121 of the base plate 120. The vibrator 131 of the piezoelectric vibrating piece 130 is disposed in the cavity 150. The cavity 150 is sealed by forming the bonding materials 140 between the bonding surface 112 of the lid plate 110 and the surface at the +Y′-axis side of the framing portion 132, and between the bonding surface 122 of the base plate 120 and the surface at the −Y′-axis side of the framing portion 132. When the extraction electrode 135 formed at the framing portion 132 electrically connects to the connecting electrode 123 formed at the base plate 120, the excitation electrode 134 electrically connects to the mounting terminal 124.

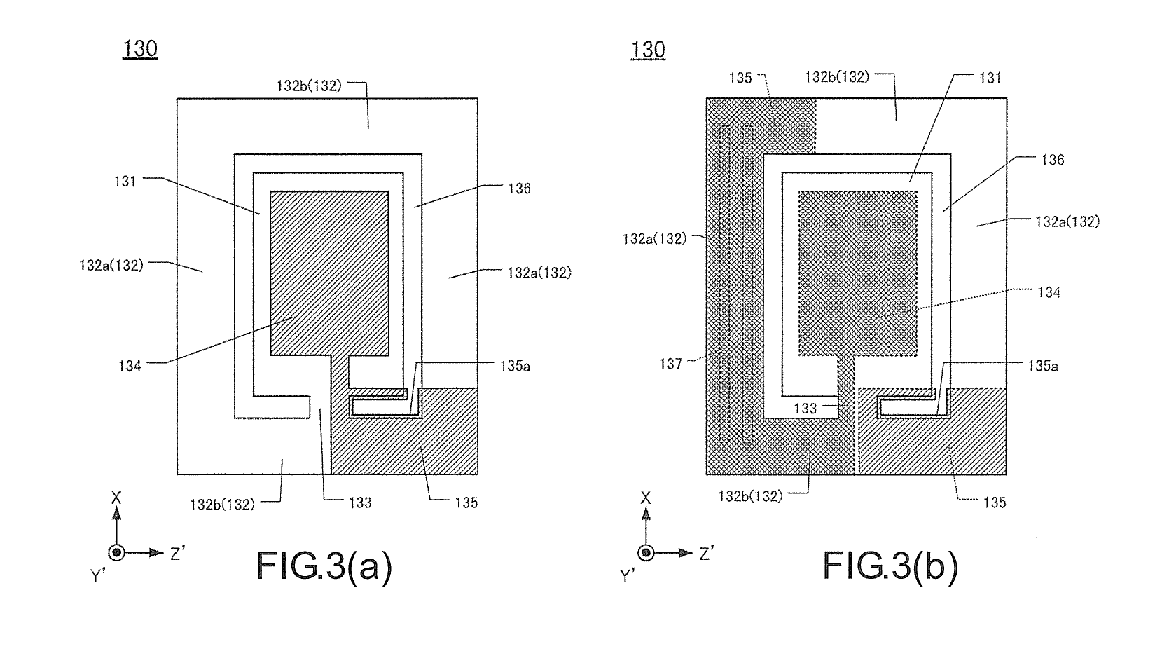

FIG. 3(a) is a plan view of the piezoelectric vibrating piece 130. The piezoelectric vibrating piece 130 is formed by connecting the center of the side at the −X-axis side of the rectangular vibrator 131 and the center of the second framing body 132b at the −X-axis side by the connecting portion 133. The excitation electrode 134 is formed at the center of the vibrator 131. The extraction electrode 135 is extracted from the excitation electrode 134 to the −X-axis side and the +Z′-axis side of the framing portion 132. The extraction electrode 135 is extracted to the surface at the −Y′-axis side via a side surface electrode 135a. The side surface electrode 135a is a part of the extraction electrode 135 and is formed at the side surface at the end of the −X-axis side and the +Z′-axis side of the through groove 136.

FIG. 3(b) is a plan view of the piezoelectric vibrating piece 130 where the surface at the −Y′-axis side of the piezoelectric vibrating piece 130 is transparently viewed from the +Y′-axis side. The piezoelectric vibrating piece 130 includes the excitation electrode 134 at the center of the vibrator 131 on the surface at the −Y′-axis side. From this excitation electrode 134, the extraction electrode 135 is extracted to the end at the +X-axis side and the −Z′-axis side of the framing portion 132 via the connecting portion 133, the second framing body 132b at the −X-axis side, and the first framing body 132a at the −Z′-axis side. Additionally, the extraction electrode 135 extracted from the surface at the +Y′-axis side to the surface at the −Y′-axis side via the side surface electrode 135a is extracted to the end at the −X-axis side and the +Z′-axis side of the framing portion 132 on the surface at the −Y′-axis side. Two depressed portions 137 extend in the X-axis direction at the −Z′-axis side of the first framing body 132a on the surface at the −Y′-axis side.

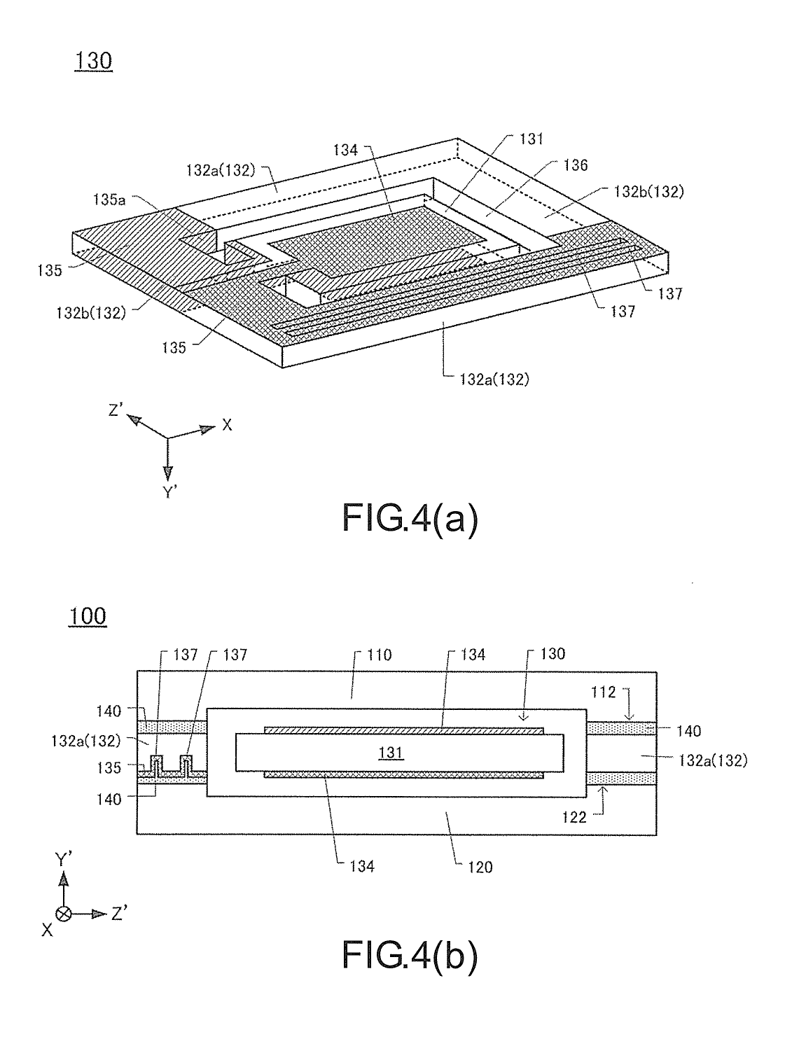

FIG. 4(a) is a perspective view of the piezoelectric vibrating piece 130 on the surface at the −Y′-axis side. The two depressed portions 137 are formed at the −Z′-axis side of the first framing body 132a on the surface at the −Y′-axis side. Each depressed portion 137 is formed from near the end portion at the −X-axis side to near the end portion at the +X-axis side at the −Z′-axis side of the first framing body 132a. The extraction electrode 135 is formed at the entire depressed portions 137. Forming the depressed portion 137 expands the surface area of the extraction electrode 135 formed at the −Z′-axis side of the first framing body 132a on the surface at the −Y′-axis side compared with the case where the depressed portion 137 is not formed.

FIG. 4(b) is a cross-sectional view taken along the line B-B of FIG. 1. The depressed portion 137 is formed at the first framing body 132a at the −Z′-axis side of the piezoelectric vibrating piece 130. Forming the extraction electrode 135 at the depressed portion 137 expands the width of the extraction electrode 135 relative to a current flowing in the X-axis direction. An electrical resistance is reduced at the extraction electrode 135 formed at the −Z′-axis side of the first framing body 132a relative to a current flowing in the X-axis direction. Accordingly, a crystal impedance (CI) of the piezoelectric vibrating piece 130 can be decreased.

### Second Embodiment

With the piezoelectric vibrating piece 130, various modifications are applicable to shapes of a depressed portion and the piezoelectric vibrating piece. A description will be given of the modifications of the piezoelectric vibrating piece 130, which includes a piezoelectric vibrating piece 230, a piezoelectric vibrating piece 330, and a piezoelectric vibrating piece 430. Like reference numerals designate corresponding or identical elements throughout the first embodiment and the second embodiment, and therefore such elements will not be further elaborated here.

### Constitution of the Piezoelectric Vibrating Piece 230

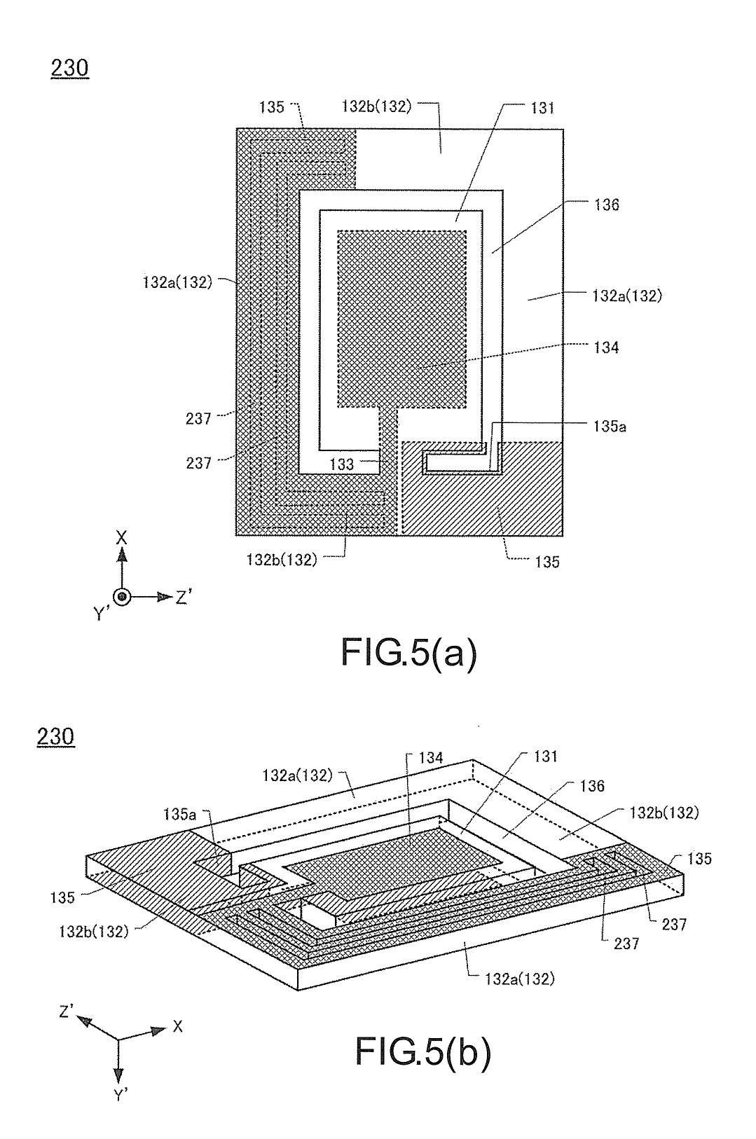

FIG. 5(a) is a plan view of the piezoelectric vibrating piece 230 on the surface at the −Y′-axis side transparently viewed from the +Y′-axis side. The piezoelectric vibrating piece 230 includes the vibrator 131, the framing portion 132, and the connecting portion 133. The piezoelectric vibrating piece 230 further includes the excitation electrode 134 and the extraction electrode 135. Two depressed portions 237 are formed at the −X-axis side and the −Z′-axis side of the second framing body 132b, at the −Z′-axis side of the second framing body 132b, and near the end portion at the −Z′-axis side and the +X-axis side of the framing portion 132 on the framing portion 132 on the surface at the −Y′-axis side where the extraction electrode 135 is formed. The piezoelectric vibrating piece 230 has the surface at the +Y′-axis side same as that in FIG. 3(a).

FIG. 5(b) is a perspective view of the piezoelectric vibrating piece 230 on the surface at the −Y′-axis side. The extraction electrode 135 is formed at the entire depressed portions 237 formed at the piezoelectric vibrating piece 230. Forming the depressed portion 237 expands the surface area of the extraction electrode 135 formed from the second framing body 132b at the −X-axis side to near the −Z′-axis side of the second framing body 132b at the +X-axis side via the first framing body 132a at the −Z′-axis side compared with the case where the depressed portion 237 is not formed. Since this widens the extraction electrode 135 relative to a current flowing in the X-axis direction, an electrical resistance is reduced. Accordingly, a crystal impedance (CI) of the piezoelectric vibrating piece 230 can be decreased.

### Constitution of a Piezoelectric Vibrating Piece 330

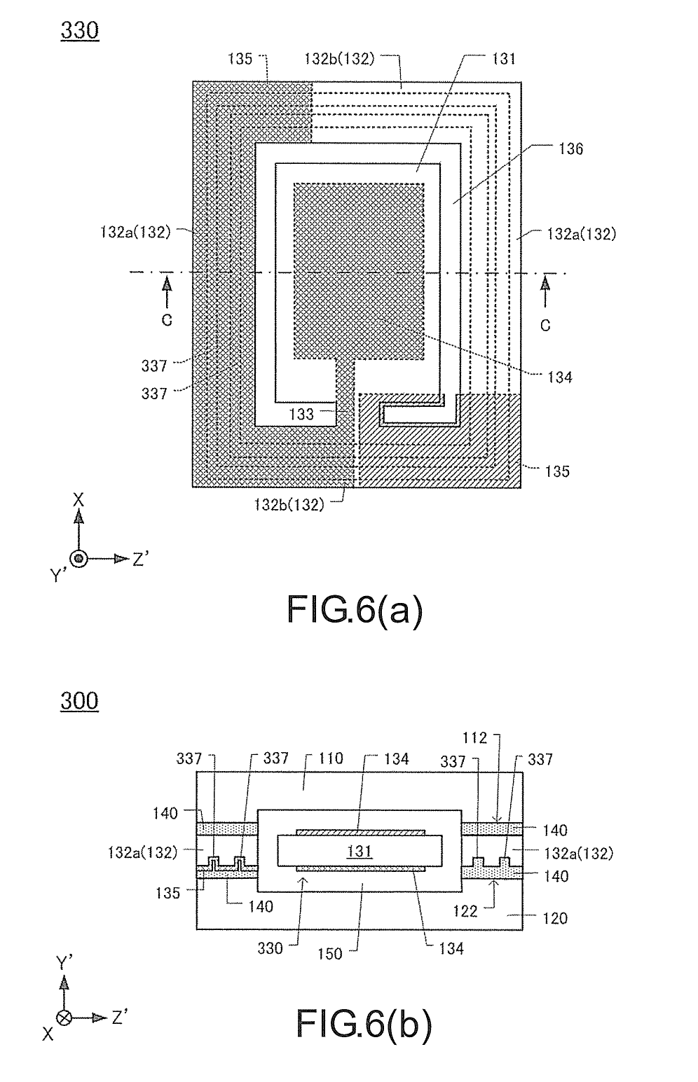

FIG. 6(a) is a plan view of the piezoelectric vibrating piece 330 on the surface at the −Y′-axis side transparently viewed from the +Y′-axis side. The piezoelectric vibrating piece 330 includes the vibrator 131, the framing portion 132, and the connecting portion 133. The framing portion 132 includes two depressed portions 337 on the surface at the −Y′-axis side. The depressed portions 337 are depressed from the framing portion 132 on the surface at the −Y′-axis side in the +Y′-axis direction and surround the peripheral area of the vibrator 131. The surface at the +Y′-axis side of the piezoelectric vibrating piece 330 is the same as that in FIG. 3(a).

FIG. 6(b) is a cross-sectional view of a piezoelectric device 300. FIG. 6(b) is a cross-sectional view including a cross section taken along the line C-C of FIG. 6(a). The piezoelectric device 300 includes a piezoelectric vibrating piece 330, the base plate 120, and the lid plate 110. The base plate 120 is to be bonded on the −Y′-axis side of the piezoelectric vibrating piece 330. The lid plate 110 is to be bonded on the surface at the +Y′-axis side of the piezoelectric vibrating piece 330. The piezoelectric vibrating piece 330 includes the depressed portion 337 at the framing portion 132 on the surface at the −Y′-axis side. The surface at the −Y′-axis side of the framing portion 132 is bonded to the bonding surface 122 of the base plate 120 via the bonding material 140. The depressed portion 337 is formed corresponding to the bonding surface 122 that surrounds the peripheral area of the cavity 150 formed in the piezoelectric device 300. This allows uniformly bonding the framing portion 132 and the bonding surface 122 without forming unevenness in bonding strength. Accordingly, stress applied between the framing portion 132 and the bonding surface 122 does not concentrate at a specific portion but disperses. Consequently, the bonding strength between the framing portion 132 and the bonding surface 122 improves, and this also improves sealing strength of the cavity 150.

### Constitution of a Piezoelectric Vibrating Piece 430

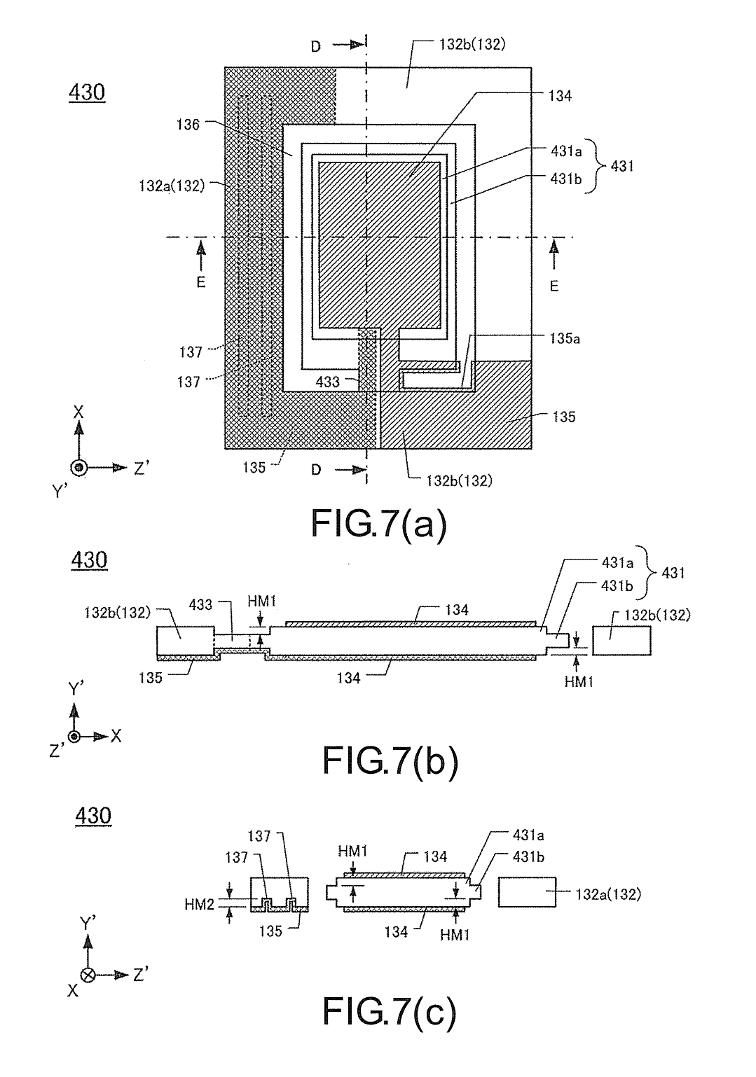

FIG. 7(a) is a plan view of the piezoelectric vibrating piece 430. FIG. 7(a) illustrates an electrode and depressed portions formed on the surface at the −Y′-axis side by dotted lines. The piezoelectric vibrating piece 430 includes a vibrator 431, the framing portion 132, and a connecting portion 433. The vibrator 431 is formed at the center of the vibrator 431. The vibrator 431 includes a mesa region 431a and a peripheral region 431b. The mesa region 431a includes the excitation electrode 134. The peripheral region 431b is a region other than the mesa region 431a and surrounds the mesa region 431a. From the excitation electrodes 134 formed at the mesa regions 431a, the respective extraction electrodes 135 are extracted to the framing portion 132 through the peripheral region 431b and the connecting portion 433.

FIG. 7(b) is a cross-sectional view taken along the line D-D of FIG. 7(a). The piezoelectric vibrating piece 430 includes steps between the mesa region 431a at the +Y′-axis side and the peripheral region 431b, and between the mesa region 431a at the −Y′-axis side and the peripheral region 431b. The mesa region 431a is formed thicker than the peripheral region 431b in the Y′-axis direction. A height HM1 of the step at the surface at the +Y′-axis side of the vibrator 431 is equal to a height HM1 of the step at the surface at the −Y′-axis side of the vibrator 431. Additionally, the connecting portion 433 has the same thickness as a thickness of the peripheral region 431b.

FIG. 7(c) is a cross-sectional view taken along the line E-E of FIG. 7(a). The two depressed portions 137 are formed at the first framing body 132a at the −Z′-axis side on the surface at the −Y′-axis side. Assume that the depth of this depressed portion 137 is HM2. With the piezoelectric vibrating piece 430, the height HM1, which is the height of the mesa region 431a, and the depth HM2 are the same. The mesa region 431a and the depressed portion 137 can be formed by wet-etching the piezoelectric vibrating piece 430. With the same dimension of the height HM1 and the depth HM2, the mesa region 431a and the depressed portion 137 can be simultaneously formed by etching. This allows simplifying a formation process of the piezoelectric vibrating piece 430.

### Third Embodiment

An extruding part may be formed instead of a depressed portion formed at a framing portion of a piezoelectric vibrating piece. A description will be given of a piezoelectric vibrating piece 630 where the extruding part is formed. Like reference numerals designate corresponding or identical elements throughout the first embodiment and the third embodiment, and therefore such elements will not be further elaborated here.

### Constitution of the Piezoelectric Vibrating Piece 630

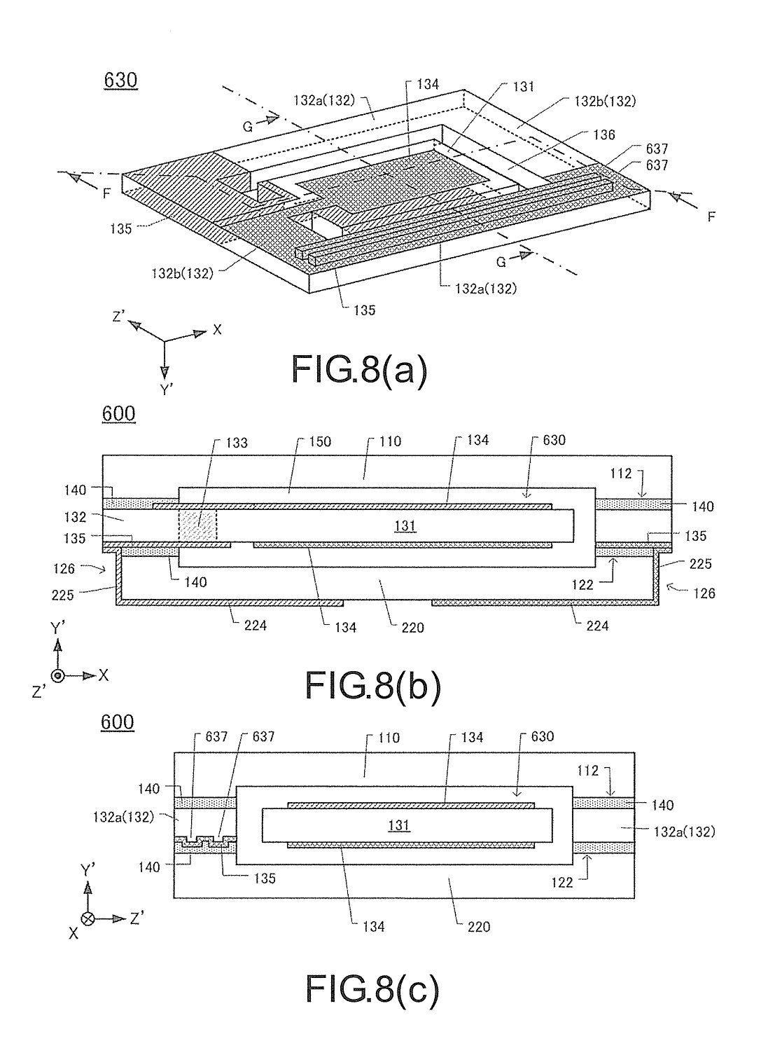

FIG. 8(a) is a perspective view of the piezoelectric vibrating piece 630 on the surface at the −Y′-axis side. The piezoelectric vibrating piece 630 includes two extruding parts 637 instead of the depressed portions 137 in the piezoelectric vibrating piece 130 (see FIG. 4(a)). The two extruding parts 637 protrude from the framing portion 132 in the −Y′-axis direction on the surface at the −Y′-axis side extending parallel with one another in the X-axis direction.

FIG. 8(b) is a cross-sectional view of the piezoelectric device 600. The piezoelectric device 600 includes the lid plate 110, a base plate 220, and the piezoelectric vibrating piece 630. FIG. 8(b) illustrates a cross-sectional view including a cross section taken along the line F-F of FIG. 8(a). The base plate 220 has the same shape as the base plate 120 (see FIG. 1) excluding an electrode. A pair of mounting terminals 224 is formed at the base plate 220 on the surface at the −Y′-axis side. A castellation electrode 225 is formed at the castellation 126. The castellation electrode 225 electrically connects to the mounting terminal 224 and the extraction electrode 135. With the piezoelectric device 600, forming an electrode on the base plate after bonding of the piezoelectric vibrating piece 630 and the base plate 220 electrically connects the extraction electrode 135 and the castellation electrode 225.

FIG. 8(c) is a cross-sectional view of the piezoelectric device 600. FIG. 8(c) is a cross-sectional view including a cross section taken along the line G-G of FIG. 8(a). Forming the extruding part 637 at the first framing body 132a of the piezoelectric vibrating piece 630 expands the surface area of the extraction electrode 135 formed at the first framing body 132a on the surface at the −Y′-axis side. Since this widens the extraction electrode 135, which is formed on the first framing body 132a on the surface at the −Y′-axis side, relative to a current flowing in the X-axis direction, an electrical resistance is reduced relative to the current flowing in the X-axis direction. Accordingly, a crystal impedance (CI) value of the piezoelectric vibrating piece 630 can be decreased.

### Fourth Embodiment

An extraction electrode formed at a framing portion of a piezoelectric vibrating piece may be formed at an inner side surface of a framing portion facing a vibrator. A description will be given of a piezoelectric vibrating piece 730 where an extraction electrode is formed at the inner side surface. Like reference numerals designate corresponding or identical elements throughout the first embodiment and the fourth embodiment, and therefore such elements will not be further elaborated here.

### Constitution of the Piezoelectric Vibrating Piece 730

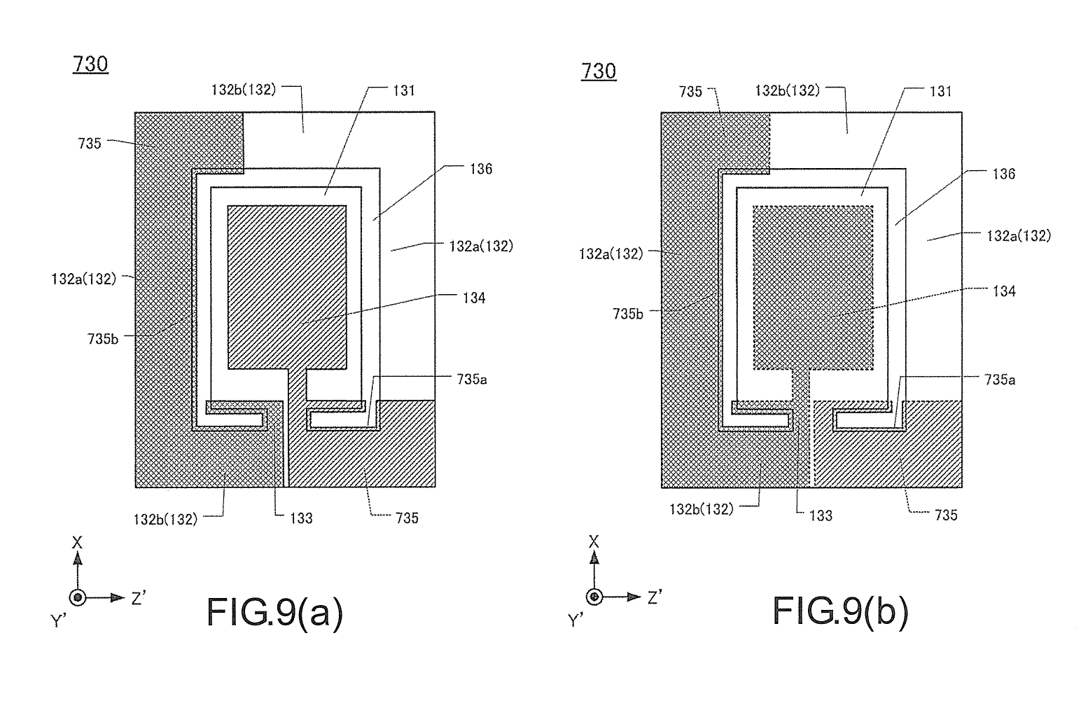

FIG. 9(a) is a plan view of the piezoelectric vibrating piece 730 at the +Y′-axis side. The piezoelectric vibrating piece 730 includes the vibrator 131, the framing portion 132, and the connecting portion 133. An extraction electrode 735 is extracted from the excitation electrode 134 formed at the vibrator 131 on the surface at the +Y′-axis side. The extraction electrode 735 is extracted to the second framing body 132b at the −X-axis side via the connecting portion 133. The extraction electrode 735 is further extracted to the surface at the −Y′-axis side via a side surface electrode 735a. The side surface electrode 735a is a part of the extraction electrode 735 formed on the side surface near the −X-axis side and the +Z′-axis side of the through groove 136. The extraction electrode 735 is formed at the −Z′-axis side of the second framing body 132b at the −X-axis side, at the −Z′-axis side of the first framing body 132a, and at the −Z′-axis side of the second framing body 132b at the +X-axis side at the framing portion 132 on the surface at the +Y′-axis side. The extraction electrode 735 is extracted from the surface at the −Y′-axis side via a side surface electrode 735b, which is a part of the extraction electrode 735. The side surface electrode 735b is formed near the −Z′-axis side and the −X-axis side of the through groove 136, at an inner side surface at the −Z′-axis side of the first framing body 132a facing the vibrator 131, and at the −Z′-axis side of the inner side surface at the +X-axis side of the second framing body 132b facing the vibrator 131.

FIG. 9(b) is a plan view of the piezoelectric vibrating piece 730 on the surface at the −Y′-axis side viewed from the +Y′-axis side. The extraction electrode 735 is extracted from the excitation electrode 134 formed in the vibrator 131 at the −Y′-axis side. The extraction electrode 735 is formed to the corner at the +X-axis side and the −Z′-axis side of the framing portion 132 through the connecting portion 133 and the first framing body 132a at the −Z′-axis side. The extraction electrode 735 is further extracted to the framing portion 132 on the surface at the +Y′-axis side via the side surface electrode 735b. The extraction electrode 735 is also extracted from the surface at the +Y′-axis side to the −X-axis side and the +Z′-axis side of the framing portion 132 on the surface at the −Y′-axis side via the side surface electrode 735a.

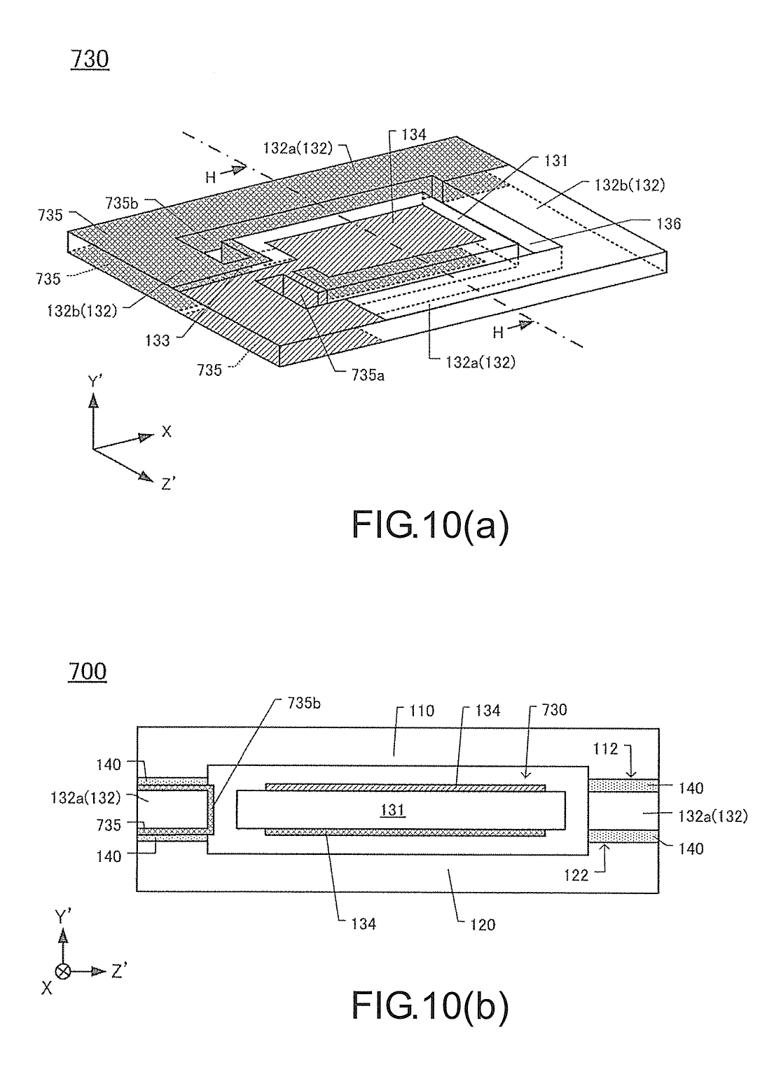

FIG. 10(a) is a perspective view of the piezoelectric vibrating piece 730. The extraction electrode 735 is extracted from the excitation electrode 134, which is formed on the surface at the +Y′-axis side, to the −X-axis side and the +Z′-axis side of the framing portion 132 on the surface at the −Y′-axis side via the side surface electrode 735a. The extraction electrode 735 is also extracted from the excitation electrode 134 formed on the surface at the −Y′-axis side. The extraction electrode 735 passes through the connecting portion 133, the second framing body 132b at the −X-axis side, and the first framing body 132a at the −Z′-axis side and is formed to the corner at the +X-axis side and the −Z′-axis side on the surface at the −Y′-axis side of the framing portion 132. With the piezoelectric vibrating piece 730, the extraction electrode 735 is formed from the excitation electrode 134 to a connection position with the connecting electrode 123 (see FIG. 1) across the entire framing portion 132 excluding an outer side surface. The surface area of the extraction electrode 735 is expanded.

FIG. 10(b) is a cross-sectional view of a piezoelectric device 700. FIG. 10(b) is a cross-sectional view including a cross section taken along the line H-H of FIG. 10(a). The piezoelectric device 700 includes the lid plate 110, the base plate 120, and the piezoelectric vibrating piece 730. The extraction electrode 735, which is formed on the first framing body 132a at the −Z′-axis side of the piezoelectric vibrating piece 730, is formed at the inner side surface at the −Y′-axis side, the +Y′-axis side, and the +Z′-axis side of the first framing body 132a. This expands the area of the extraction electrode 735 relative to a current flowing in the X-axis direction, decreasing an electrical resistance. Accordingly, a crystal impedance (CI) of the piezoelectric vibrating piece 730 can be decreased.

With the piezoelectric vibrating piece 730, forming the extraction electrode 735 at the inner side surface of the framing portion 132 facing the vibrator 131 or similar member expands the surface area of the extraction electrode 735. Accordingly, the crystal impedance (CI) of the piezoelectric vibrating piece 730 can be decreased. With the piezoelectric vibrating piece 730, the extraction electrode 735 is also formed on the first framing body 132a at the −Z′-axis side on the surface at the +Y′-axis side or similar region. Simply forming the side surface electrode 735b in addition to the framing portion 132 on the surface at the −Y′-axis side also expands the surface area of the extraction electrode 735, decreasing the crystal impedance (CI) of the piezoelectric vibrating piece 730.

### Fifth Embodiment

A piezoelectric vibrating piece may be formed in combination with the features of the piezoelectric vibrating pieces according to the first embodiment to the third embodiment and the fourth embodiment. A description will be given of a piezoelectric vibrating piece 830 and a piezoelectric vibrating piece 930 where an extraction electrode is formed at an inner side surface and a depressed portion is formed. Like reference numerals designate corresponding or identical elements throughout the first embodiment to the fourth embodiment and the fifth embodiment, and therefore such elements will not be further elaborated here.

### Constitution of the Piezoelectric Vibrating Piece 830

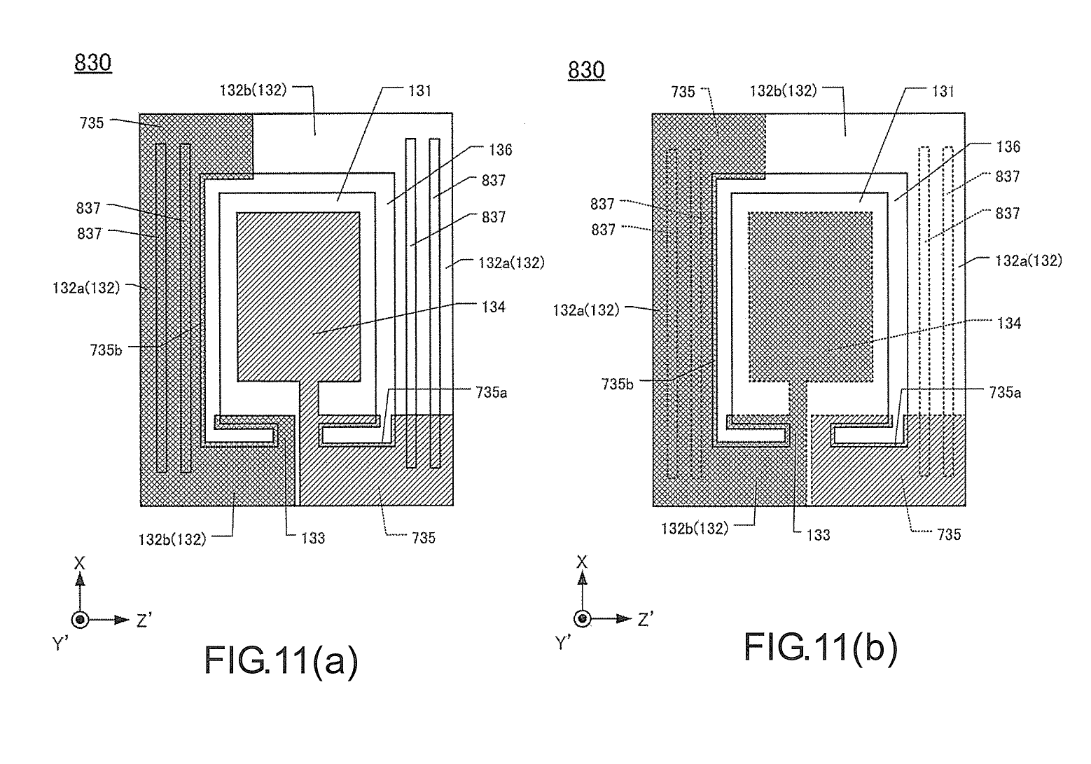

FIG. 11(a) is a plan view of the piezoelectric vibrating piece 830 on the surface at the +Y′-axis side. The piezoelectric vibrating piece 830 is a piezoelectric vibrating piece where a depressed portion 837 is formed at the framing portion 132 of the piezoelectric vibrating piece 730. The piezoelectric vibrating piece 830 includes the two depressed portions 837 on the respective first framing bodies 132a at the +Z′-axis side and the −Z′-axis side on the surface at the +Y′-axis side. Each depressed portion 837 extends in the X-axis direction. The depressed portions 837 formed at the +Z′-axis side of the first framing body 132a and the depressed portions 837 formed at the −Z′-axis side of the first framing body 132a are disposed to be a mirror symmetry with respect to a straight line, which passes through the center of the piezoelectric vibrating piece 830, in parallel with the X-axis.

FIG. 11(b) is a plan view of the piezoelectric vibrating piece 830 on the surface at the −Y′-axis side. The piezoelectric vibrating piece 830 includes the two depressed portions 837 on the respective first framing bodies 132a at the +Z′-axis side and the −Z′-axis side on the surface at the −Y′-axis side. Each depressed portion 837 extends in the X-axis direction. The depressed portions 837 formed at the +Z′-axis side of the first framing body 132a and the depressed portions 837 formed at the −Z′-axis side of the first framing body 132a are disposed to be a mirror symmetry with respect to a straight line, which passes through the center of the piezoelectric vibrating piece 830, in parallel with the X-axis. Additionally, the depressed portions 837 formed at each first framing body 132a on the surfaces at the +Y′-axis side and the −Y′-axis side are formed overlapping one another in the Y′-axis direction.

With the piezoelectric vibrating piece 830, forming the depressed portion 837 expands the surface area of the extraction electrode 735 and decreases a crystal impedance (CI) of the piezoelectric vibrating piece 830. Further, the depressed portions 837 formed at the +Z′-axis side and the −Z′-axis side of the first framing bodies 132a are mirror symmetry with one another, and the depressed portions 837 formed at the +Y′-axis side and the −Y′-axis side of the first framing bodies 132a are formed overlapping one another. These disperse stress applied to the framing portion 132; therefore, strength of the piezoelectric device improves and stress applied to a bonding portion between the framing portion 132 and a lid plate and a bonding portion between the framing portion 132 and a base plate disperses, thus sealing strength of a cavity improves. Forming the depressed portions symmetrically thus disperses stress applied to the piezoelectric device. Further, the piezoelectric vibrating piece 830 may include a depressed portion only either one of the +Y′-axis side and the −Y′-axis side.

### Constitution of the Piezoelectric Vibrating Piece 930

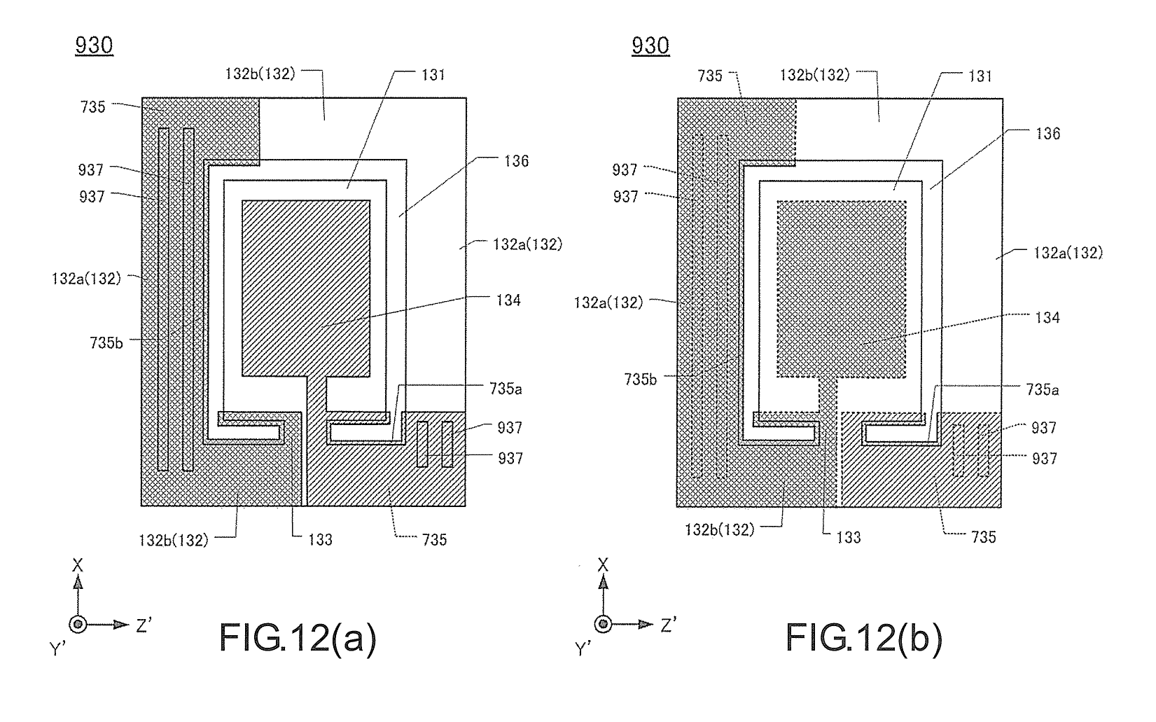

FIG. 12(a) is a plan view of the piezoelectric vibrating piece 930 on the surface at the +Y′-axis side. The piezoelectric vibrating piece 930 is a piezoelectric vibrating piece where a depressed portion 937 is formed at the framing portion 132 of the piezoelectric vibrating piece 730. The piezoelectric vibrating piece 930 includes the two depressed portions 937 on the first framing body 132a at the −Z′-axis side on the surface at the +Y′-axis side. The depressed portions 937 extend in the X-axis direction. The two depressed portions 937 are formed at a region at the −X-axis side of the first framing body 132a at the +Z′-axis side where the extraction electrode 735 is formed. The depressed portions 937 extend in the X-axis direction.

FIG. 12(b) is a plan view of the piezoelectric vibrating piece 930 on the surface at the −Y′-axis side. The piezoelectric vibrating piece 930 includes the two depressed portions 937 on the first framing body 132a at the −Z′-axis side on the surface at the −Y′-axis side. The depressed portions 937 extend in the X-axis direction. The two depressed portions 937 are formed at a region at the −X-axis side of the first framing body 132a at the +Z′-axis side where the extraction electrode 735 is formed. The depressed portions 937 extend in the X-axis direction.

With the piezoelectric vibrating piece 930, forming the depressed portions 937 on both pair of extraction electrodes 735 expands the surface area of the extraction electrode 735. Thus, a crystal impedance (CI) of the piezoelectric vibrating piece 930 can be decreased. Further, the piezoelectric vibrating piece 930 may include a depressed portion 937 only either one of the +Y′-axis side and the −Y′-axis side.

The piezoelectric vibrating piece 730 may include the depressed portion 137 illustrated in FIG. 3(b) or the depressed portion 337 illustrated in FIG. 6(a) on at least one of the surface at the +Y′-axis side or the surface at the −Y′-axis side. This decreases the crystal impedance (CI) of the piezoelectric vibrating piece and improves the strength of the piezoelectric vibrating piece or the piezoelectric device. Additionally, these depressed portions may be extruding parts.

### Sixth Embodiment

The piezoelectric vibrating pieces according to the first embodiment to the third embodiment may include depressed portions or extruding parts, which are formed at the framing portion of the piezoelectric vibrating piece, on the framing portions on both surfaces at the +Y′-axis side and the −Y′-axis side. A description will be given of a piezoelectric vibrating piece 1030 where the depressed portions are formed on the framing portions on the surface at the +Y′-axis side and on the surface at the −Y′-axis side. The following embodiment describes the case where the depressed portion is formed; however, the extruding part may be formed instead of the depressed portion. Like reference numerals designate corresponding or identical elements throughout the first embodiment and the second embodiment and the sixth embodiment, and therefore such elements will not be further elaborated here.

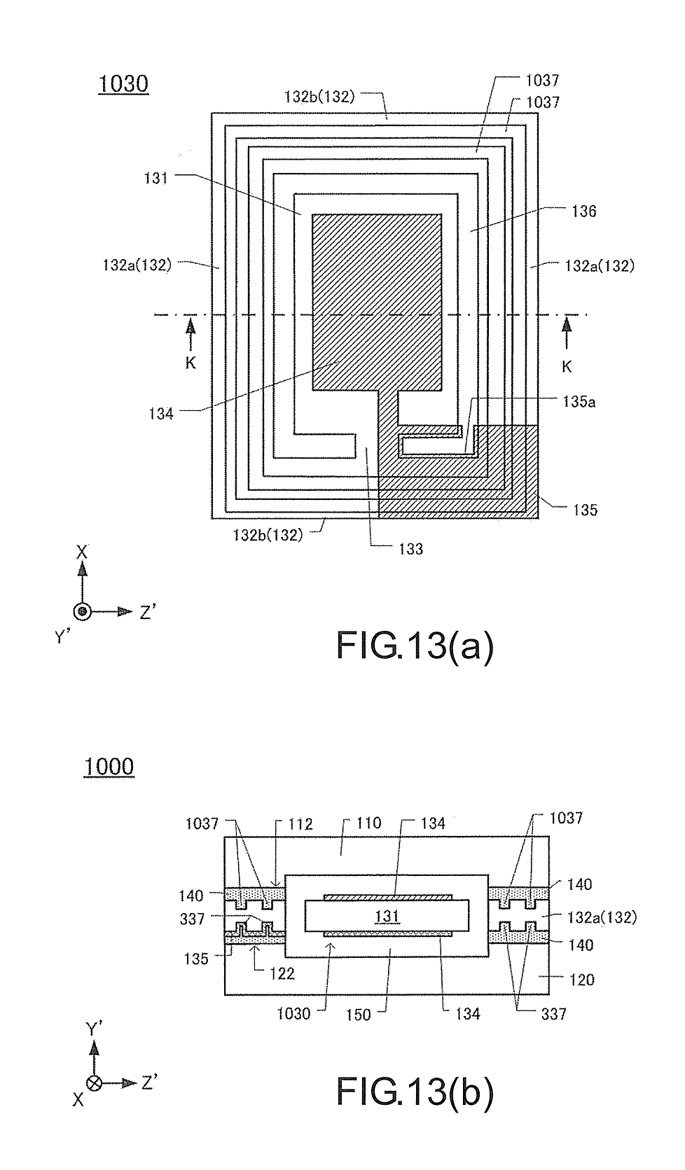

FIG. 13(a) is a plan view of the piezoelectric vibrating piece 1030. The piezoelectric vibrating piece 1030 in FIG. 13(a) includes the vibrator 131, the framing portion 132, and the connecting portion 133. The framing portion 132 includes two depressed portions 1037 on the surface at the +Y′-axis side. The depressed portions 1037 are depressed from the framing portion 132 on the surface at the +Y′-axis side in the −Y′-axis direction and surround the peripheral area of the vibrator 131. The piezoelectric vibrating piece 1030 has the surface at the −Y′-axis side the same as that in FIG. 6(a). Additionally, the depressed portions 337 (see FIG. 6(a)) and the depressed portion 1037 are formed overlapping one another in the Y′-axis direction.

FIG. 13(b) is a cross-sectional view of the piezoelectric device 1000. FIG. 13(b) is a cross-sectional view including a cross section taken along the line K-K of FIG. 13(a). The piezoelectric device 1000 includes the piezoelectric vibrating piece 1030, the base plate 120, and the lid plate 110. The base plate 120 is to be bonded at the −Y′-axis side of the piezoelectric vibrating piece 1030. The lid plate 110 is to be bonded on the surface at the +Y′-axis side of the piezoelectric vibrating piece 1030. The piezoelectric vibrating piece 1030 includes a depressed portion 1037 at the framing portion 132 on the surface at the +Y′-axis side. The surface of the framing portion 132 at the +Y′-axis side is bonded to the bonding surface 112 of the lid plate 110 via the bonding material 140. The piezoelectric vibrating piece 1030 includes the depressed portion 337 at the framing portion 132 on the surface at the −Y′-axis side. The surface at the −Y′-axis side of the framing portion 132 is bonded to the bonding surface 122 of the base plate 120 via the bonding material 140.

With the piezoelectric device 1000, the depressed portion 337 and the depressed portion 1037 are formed corresponding to the bonding surface 122 and the bonding surface 112. This allows uniformly bonding between the framing portion 132 and the bonding surface 122 and between the framing portion 132 and the bonding surface 112 without causing unevenness in bonding strength. Accordingly, stress applied between the framing portion 132 and the bonding surface 122 does not concentrate at a specific portion but disperses. Consequently, the bonding strength between the framing portion 132 and the bonding surface 122 and between the framing portion 132 and the bonding surface 112 improves, and this also improves sealing strength of the cavity 150. Additionally, with the piezoelectric vibrating piece 1030, the depressed portions 337 and the depressed portions 1037 formed at the framing portions 132 are disposed to be mirror symmetry with one another at the +Z′-axis side and the −Z′-axis side of the framing portion 132 and are formed overlapping in the Y′-axis direction of the framing portion 132. This disperses stress applied to the framing portion 132, and therefore the strength of the piezoelectric device is increased.

Representative embodiments are described in detail above; however, as will be evident to those skilled in the relevant art, this disclosure may be changed or modified in various ways within its technical scope.

For example, a plurality of the above-described embodiments may be employed in combination. This may further decrease a crystal impedance (CI). The above-described embodiments disclose the case where two depressed portions and two extruding parts are employed. However, a single or equal to or more than three depressed portions and extruding parts may be employed. Additionally, the above-described embodiments disclose a case where the piezoelectric vibrating piece is an AT-cut quartz-crystal vibrating piece. A BT-cut quartz-crystal vibrating piece or similar member that similarly vibrates in the thickness-shear mode is similarly applicable. Further, the piezoelectric vibrating piece is basically applicable to a piezoelectric material that includes not only a quartz-crystal material but also lithium tantalate, lithium niobate, and piezoelectric ceramics.

The piezoelectric device according to the above-described embodiments may include a grounding terminal that grounds the piezoelectric device or similar member as well as a mounting terminal. Additionally, the piezoelectric device can include an integrated circuit and be formed as a piezoelectric oscillator.

In the first aspect of the disclosure, the piezoelectric vibrating piece according to a second aspect is configured as follows. The extraction electrode is disposed via the second framing body. The depressed portion or the extruding part is also disposed on a region of the second framing body where the extraction electrode is formed.

In the first aspect and the second aspect of the disclosure, the piezoelectric vibrating piece according to a third aspect is configured as follows. The depressed portion or the extruding part surrounds the vibrator at the framing body on the one principal surface.

In the first aspect to the third aspect of the disclosure, the piezoelectric vibrating piece according to a fourth aspect is configured as follows. A plurality of the depressed portions or the extruding parts is disposed on the first framing body.

In the first aspect to the fourth aspect of the disclosure, the piezoelectric vibrating piece according to a fifth aspect is configured as follows. The extraction electrode is extracted from the excitation electrode formed on the one principal surface.

In the first aspect to the fifth aspect of the disclosure, the piezoelectric vibrating piece according to a sixth aspect is configured as follows. The extraction electrode is also disposed at an inner side surface of the first framing body facing the vibrator.

In the first aspect to the sixth aspect of the disclosure, the piezoelectric vibrating piece according to a seventh aspect is configured as follows. The vibrator includes a mesa portion and a peripheral portion on at least one of the principal surfaces. The mesa portion is disposed at a center of the principal surface. The excitation electrode is disposed on the mesa portion. The peripheral portion is a region other than the mesa portion. The peripheral portion is thinner than the mesa portion. The mesa portion has a step height from the peripheral portion. The step height is equal to a depth of the depressed portion or a height of the extruding part.

The piezoelectric vibrating piece according to an eighth aspect is configured as follows. A vibrator has a rectangular shape and vibrates at a predetermined vibration frequency. The vibrator includes excitation electrodes on both principal surfaces. A framing portion surrounds a peripheral area of the vibrator. The framing portion includes a pair of first framing bodies and a pair of second framing bodies. The pair of first framing bodies extends in a long side direction. The pair of second framing bodies extends in a short side direction. A connecting portion connects the vibrator and the one second framing body. An extraction electrode is extracted from the excitation electrode on the one principal surfaces via the one principal surface of the connecting portion, one of the second framing bodies on the one principal surface, and one of the first framing bodies on the one principal surface. The extraction electrode is extracted to another of the second framing bodies on the one principal surface. The extraction electrode is disposed on an entire surface of an inner side surface of one of the one first framing bodies facing the vibrator, the inner side surface of the connecting portion, and the inner side surface of one of the second framing bodies.

In the eighth aspect of the disclosure, the piezoelectric vibrating piece according to a ninth aspect is configured as follows. The extraction electrode is further disposed on another principal surface of the connecting portion, another principal surface of the one of the second framing bodies, and another principal surface of the one of the first framing bodies.

A piezoelectric device according to a tenth aspect is configured as follows. The piezoelectric vibrating piece is according to the first aspect to the ninth aspect of the disclosure. A base plate is bonded on one principal surface of the framing portion. A lid plate is bonded on another principal surface of the framing portion to seal the vibrator.

With the piezoelectric vibrating piece and the piezoelectric device according to the embodiments, expanding a surface area of an extraction electrode formed at a framing portion allows lowering an electrical resistance of the extraction electrode.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
a vibrator, having a rectangular shape, the vibrator vibrating at a predetermined vibration frequency, the vibrator including excitation electrodes on both principal surfaces;
a framing portion, surrounding a peripheral area of the vibrator, the framing portion including a first framing body and a second framing body, the first framing body extending in a long side direction, the second framing body extending in a short side direction; and
a connecting portion, connecting the vibrator and the framing portion, wherein
the first framing body includes a depressed portion or an extruding part on one principal surface, the depressed portion or the extruding part extending in a long side direction, and
the piezoelectric vibrating piece further includes an extraction electrode extending from the excitation electrode via the connecting portion, the extraction electrode extending from one end to another end of the one principal surface of the first framing body, the first framing body including the depressed portion or the extruding part.

2. The piezoelectric vibrating piece according to claim 1, wherein
the extraction electrode is disposed via the second framing body, and
the depressed portion or the extruding part is also disposed on a region of the second framing body where the extraction electrode is formed.

3. The piezoelectric vibrating piece according to claim 1, wherein
the depressed portion or the extruding part surrounds the vibrator at the framing body on the one principal surface.

4. The piezoelectric vibrating piece according to claim 1, wherein
a plurality of the depressed portions or the extruding parts is disposed on the first framing body.

5. The piezoelectric vibrating piece according to claim 1, wherein
the extraction electrode is extracted from the excitation electrode formed on the one principal surface.

6. The piezoelectric vibrating piece according to claim 1, wherein
the extraction electrode is also disposed at an inner side surface of the first framing body facing the vibrator.

7. The piezoelectric vibrating piece according to claim 1, wherein
the vibrator includes a mesa region and a peripheral region on at least one of the principal surfaces, the mesa region being disposed at a center of the principal surface, the excitation electrode being disposed on the mesa region, the peripheral region being a region other than the mesa region, the peripheral region being thinner than the mesa region, and
the mesa region has a step height from the peripheral region, the step height being equal to a depth of the depressed portion or a height of the extruding part.

8. A piezoelectric vibrating piece, comprising:
a vibrator, having a rectangular shape, the vibrator vibrating at a predetermined vibration frequency, the vibrator including excitation electrodes on both principal surfaces;
a framing portion, surrounding a peripheral area of the vibrator, the framing portion including a pair of first framing bodies and a pair of second framing bodies, the pair of first framing bodies extending in a long side direction, the pair of second framing bodies extending in a short side direction;
a connecting portion, connecting the vibrator and the one second framing body; and
an extraction electrode, being extracted from the excitation electrode on the one principal surfaces via the one principal surface of the connecting portion, one of the second framing bodies on the one principal surface, and one of the first framing bodies on the one principal surface, the extraction electrode being extracted to another of the second framing bodies on the one principal surface, wherein
the extraction electrode is disposed on an entire surface of an inner side surface of one of the first framing bodies facing the vibrator, the inner side surface of the connecting portion, and the inner side surface of one of the second framing bodies.

9. The piezoelectric vibrating piece according to claim 8, wherein
the extraction electrode is further disposed on another principal surface of the connecting portion, another principal surface of the one of the second framing bodies, and another principal surface of the one of the first framing bodies.

10. A piezoelectric device, comprising:
the piezoelectric vibrating piece according to claim 1;
a base plate, being bonded on one principal surface of the framing portion; and
a lid plate, being bonded on another principal surface of the framing portion to seal the vibrator.
